(19) United States
(12) Patent Application Publication
(10) Pub. No.: US 2011/0315080 A1
(43) Pub. Date: Dec. 29, 2011

(54) LIFT PIN, AND WAFER-PROCESSING APPARATUS COMPRISING SAME

(76) Inventors: Myong-Ho Choi, Cheonan-si (KR); Jin-Sung Park, Yongin-si (KR); Jin-Chul Park, Gangcheon-myeon (KR); Ji-Suk Jang, Anseong-si (KR)

(21) Appl. No.: 13/254,375

(22) PCT Filed: Mar. 4, 2010
(86) PCT No.: PCT/KR2010/001349

§ 371 Date: Sep. 1, 2011

(30) Foreign Application Priority Data
Mar. 6, 2009 (KR) 10-2009-0019052

(51) Int. Cl. C23C 16/458; C23C 16/50; C23C 16/455

(52) U.S. Cl. 118/723 E; 118/500

(57) ABSTRACT

In a lift pin and an apparatus for processing a substrate having the same, the lift pin includes a body inserted into a penetration hole of a susceptor on which the substrate is positioned and moving along the penetration hole upward and downward in a direction vertical to an upper surface of the susceptor, and a contact member secured to an upper portion of the body and comprising a soft material having hardness smaller than that of the substrate. Thus, the contact member of the lift pin makes contact with the substrate without scratches on a surface of the substrate, to thereby reduce substrate failures in the process.

### TECHNICAL FIELD

Example embodiments relate to a lift pin and an apparatus for processing a substrate having the same, and more particularly to a lift pin for lifting semiconductor wafer upward and an apparatus for processing the wafer having the same.

### BACKGROUND ART

In general, semiconductor memory devices are manufactured through a fabrication process for forming electronic circuit patterns on a wafer, an electrical die sorting (EDS) process for inspecting electrical characteristics of the circuit patterns and detecting defects from the circuit patterns and a package process for cutting out each chip from the wafer and individually packing the chip into an individual semiconductor device by. Each of the chips is sealed in an epoxy resin and a lead frame is installed to the sealed chip in the package process.

In the above conventional semiconductor manufacturing process, the circuit pattern may be formed on the wafer by a series of unit processes such as a deposition process for forming a thin layer on the wafer, a patterning process for forming a photoresist pattern on the thin layer, an etching process for etching the thin layer using the photoresist pattern an etching mask and a removal process for removing the photoresist pattern from the etched thin layer.

A plasma deposition process has been used for forming the thin layer on the wafer since the thin layer may be formed on the wafer to a small thickness at a relatively low temperature without any significant deterioration of deposition efficiency. For example, a plasma enhanced chemical vapor deposition (PECVD) process has been most widely used for forming the thin layer on the wafer. Particularly, the PECVD process generally has merits for forming a thin layer at a relatively low temperature with high deposition rate.

A conventional apparatus for the PECVD process includes a process chamber into which supply gases are supplied, a susceptor arranged in the process chamber and on which the wafer is positioned, a shower head for uniformly dispersing the source gases onto the wafer and an electrode by which a high frequency power is applied to an inside of the process chamber to transform the source gases into plasma.

When the deposition process is completed and the thin layer is formed on the wafer, the wafer is separated from the susceptor and is unloaded out of the process chamber. Particularly, a plurality of lift pins is generally popped up vertically from the susceptor and lifts up the wafer over the susceptor. Thus, the wafer and the susceptor are separated from each other.

However, since the lift pin usually comprises aluminum (Al) based material such as alumina (Al2O3) and anodized aluminum (Al) of which the hardness is much larger than that of the Si wafer, a contact surface of the wafer is frequently damaged by the lift pin. For example, a scratch defect is frequently found on a rear surface of the wafer when the wafer is unloaded out of the process chamber.

### DISCLOSURE OF THE INVENTION

### Technical Problem

Example embodiments provide a lift pin for lifting wafer upward in a process apparatus that minimizes scratch defects on a rear surface of a silicon wafer.

Other example embodiments provide an apparatus for processing the wafer using the above lift pin.

### Technical Solution

According to some example embodiments, there is provided a lift pin for moving a wafer upward or downward on a susceptor in an apparatus for processing the wafer on the susceptor. The lift pin may include a body inserted into a penetration hole of the susceptor and moving along the penetration hole upward and downward in a direction vertical to an upper surface of the susceptor, and a contact member secured to an upper portion of the body and comprising a soft material having hardness smaller than that of the wafer, the contact member making contact with the wafer without scratches on a surface of the wafer.

In an example embodiment, the contact member comprises yttrium oxide (Y2O3).

In an example embodiment, the body includes a recess portion at the upper portion thereof and the contact member is inserted into the recess portion in such a configuration that an upper portion of the contact member is protruded from the upper portion of the body.

In an example embodiment, the lift pin may further include an adhering member positioned on an inner surface of the recess portion of the body, so that the contact member is adhered to the inner surface of the recess portion of the body.

In an example embodiment, the contact member includes an air reservoir at a central bottom portion thereof, so that a residual air remaining in the recess portion of the body is hold in the air reservoir when the contact member is inserted into the recess portion of the body. For example, the contact member may be secured into the recess portion of the body.

In an example embodiment, first screw threads may be prepared on a sidewall of the contact member and second screw threads may be prepared on an inner surface of the recess portion of the body, so that the contact member may be secured to the recess portion of the body by a screw joint.

In an example embodiment, the lift pin may further include a phase transition layer interposed between the contact member and the body, so that the contact member is secured to the body by a combining force of the phase transition layer. For example, the contact member may comprise yttrium oxide (Y2O3), the body may comprise alumina (Al2O3) and the phase transition layer may comprise yttrium aluminum garnet (YAG).

In an example embodiment, the body may include a protrusion at an upper portion thereof and the contact member includes a recess into which the protrusion is inserted.

Particularly, third screw threads may be prepared on a sidewall of the protrusion and fourth screw threads may be prepared on an inner surface of the recess, so that the protrusion of the body may be inserted into the recess of the contact member by a screw joint.

In such a case, the lift pin may further include an adhering member positioned on an inner surface of the recess of the contact member.

According to other example embodiments, there is provided an apparatus for processing a substrate using the above-mentioned lift pin. The apparatus may include a process chamber into which reaction gases for the processing the substrate is supplied and providing a space for the process; a susceptor arranged in the process chamber and having a penetration hole, the substrate being positioned on the susceptor; an electrode arranged over the susceptor and to which an electronic power is applied; and a lift pin movably inserted into the penetration hole of the susceptor and lifting the substrate from the susceptor. The reaction gases may be transformed into plasma in the space of the process chamber by the electronic power. The lift pin may include a body inserted into the penetration hole and moving along the penetration hole upward and downward in a direction vertical to an upper surface of the susceptor and a contact member secured to an upper portion of the body and comprising a soft material of which a hardness is smaller than that of the substrate, so that the contact member makes contact with the substrate without scratches on a surface of the substrate.

### Advantageous Effects

According to some example embodiments of the present inventive concept, the lift pin of an apparatus for processing a substrate may comprise a soft material of which the hardness is smaller than that of silicon of the substrate, thereby minimizing the scratch defects on the rear surface of the wafer. Thus, for example, the wafer failure at the rear surface may be sufficiently reduced in a deposition process to thereby increase production yield of semiconductor devices.

### BRIEF DESCRIPTION OF THE DRAWINGS

Example embodiments will be more clearly understood from the following detailed description taken in conjunction with the accompanying drawings.

FIG. 1 is a cross sectional view illustrating a deposition apparatus for forming a thin layer on a semiconductor substrate in accordance with an example embodiment of the present inventive concept;

FIG. 2 is an enlarged view illustrating a lift pin of the deposition apparatus shown in FIG. 1; and

FIGS. 3 to 8 are enlarged views illustrating the lift pin shown in FIG. 2.

### BEST MODE FOR CARRYING OUT THE INVENTION

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings. A deposition apparatus for forming a thin layer on a semiconductor substrate such as a wafer may be provided as an example of an apparatus for processing a substrate hereinafter. However, the deposition apparatus is merely illustrative example embodiment and is not to be construed as limiting thereof. Thus, the lift pin of the present example embodiment of the present inventive concept may also be applied to various apparatus for processing the substrate such as a dry etching apparatus, a planarization apparatus and an ion implantation process just under condition that the process is performed onto the substrate positioned on a susceptor in the apparatus.

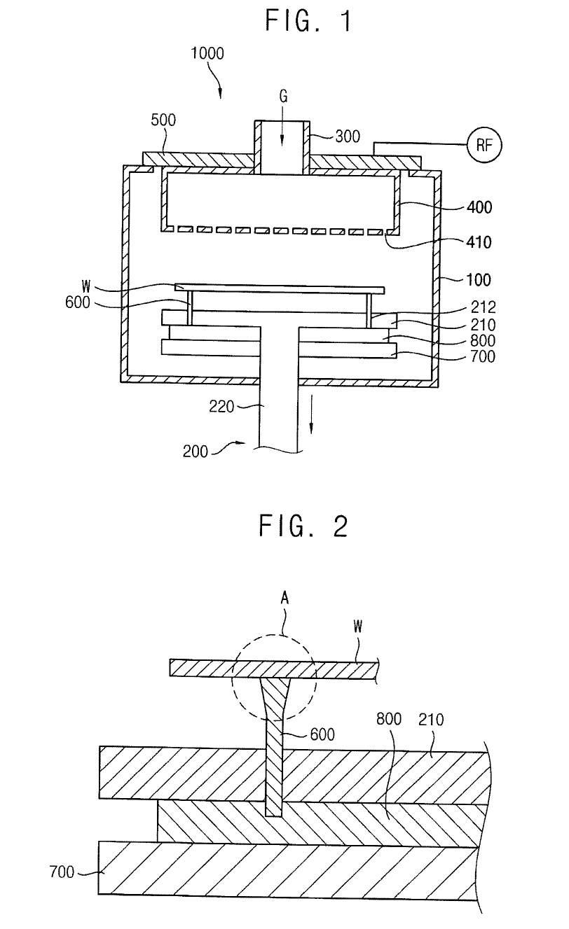

FIG. 1 is a cross sectional view illustrating a deposition apparatus for forming a thin layer on a semiconductor substrate in accordance with an example embodiment of the present inventive concept. FIG. 2 is an enlarged view illustrating a lift pin of the deposition apparatus shown in FIG. 1.

Referring to FIGS. 1 and 2, a deposition apparatus 1000 in accordance with an example embodiment of the present inventive concept may include a process chamber 100, a susceptor 200, a gas supplier 300, a shower head 400, an electrode 500 and a lift pin 600.

For example, the process chamber 100 may include a space S in which a thin layer may be formed on a semiconductor substrate comprising silicon (Si) such as a wafer W by a deposition process. An inner surface of the process chamber 100 may be coated with ceramic materials by a sprayed coating process, and thus the inner surface of the process chamber may be protected from plasma in the deposition process.

The susceptor 200 may be arranged in the process chamber 100 and the wafer W is positioned on the susceptor 200. Particularly, the susceptor 200 may include a support plate 210 on which the wafer W is positioned and a tube 220 extending from the central portion of the support plate 210 to an exterior of the process chamber 100.

For example, the support plate 210 may include a guide (not shown) for guiding the wafer W to a predetermined initial position on a top surface thereof and a heater (not shown) for heating the wafer to a deposition temperature. In addition, the support plate 210 may include a plurality of penetration hole 212.

The tube 220 may penetrate through a bottom of the process chamber 100 and may move upward and downward in a vertical direction II, and thus the support plate 210 may also be moved upward and downward by the tube 220. Electrical wirings for applying an electrical current to the heater may be built in the tube 220.

The gas supplier 300 may be arranged at an upper portion of the process chamber 100 and reaction gases G for forming a thin layer on the wafer W may be supplied into the process chamber 100 through the gas supplier 300. Thus, the reaction gases G may be supplied to the upper portion of the process chamber 100 and may flow downwards in the space S of the process chamber 100. Examples of the reaction gases G may include argon (Ar), silane (SiH4), nitrogen (N2), ammonia (NH3), chlorine (Cl2) and fluorine (F), etc. These may be used alone or in combinations thereof.

The showerhead 400 may be connected to the gas supplier 300 and the reaction gases G may be supplied onto the wafer on the susceptor 200 in the process chamber 100. A plurality of injection holes 410 may be arranged in the showerhead 400 at a uniform gap distance. Thus, the reaction gases G supplied from the gas supplier 300 may be uniformly dispersed onto the wafer W through the injection holes 410 of the showerhead 400.

The electrode 500 may be arranged over the susceptor 200. Particularly, the electrode 500 may be positioned on a top portion of the process chamber 100 over the showerhead 400 and may be electrically connected to the showerhead 400. In the present example embodiment, a radio frequency (RF) electrical power may be applied to the electrode 500. Therefore, the RF power may also be applied to the showerhead 400.

The reaction gases may be activated into plasma by the RF power and may be deposited onto the wafer W to thereby form a thin layer on the wafer W. The susceptor 200 may be grounded to surroundings and thus a ground voltage may be applied to the susceptor 200 in the deposition process.

The lift pin 600 may be arranged in the penetration hole 212 of the support plate 210 of the susceptor 200 in such a configuration that the lift pin 600 may move upwards and downwards vertically to the support plate 210. The wafer W may be loaded into the process chamber 100 and be unloaded from the process chamber 100 by the lift pin 600. Particularly, in case that the wafer W may be loaded into the process chamber 100, the wafer W may be transferred on the lift pin 600, which may be lifted relatively higher than the support plate 210, in the process chamber 100 by a transfer robot (not shown). Then, the lift pin 600 may move downward to a position lower than a surface of the support plate 210, and thus the wafer W may be loaded onto the support plate 21 in the process chamber 100.

In contrast, in case that the wafer W may be unloaded out of the process chamber 100 when completing the deposition process, the lift pin 600 may move upwards from the support plate 210 to thereby move the wafer W over the support plate 210. Then, the transfer robot may move again into a gap space between the wafer W and the support plate 210 and thus the wafer W may be supported again by the transfer robot. Thereafter, the lift pin 600 move downwards along the penetration hole 212 while the wafer W may be still supported by the transfer robot. The transfer robot may transfer the wafer W out of the process chamber 100.

In an example embodiment, an upper portion of the lift pin 600 may be reversely tapered upwards and thus the inner diameter of the upper portion of the lift 600 may be increased upwards. Therefore, when the support plate 210 may move upwards, the upper portion of the lift pin 600 may be supported by an inner surface of the penetration hole 212.

A first plate 700 and a second plate 800 may be further installed to the process chamber 100 for operating the lift pin 600.

For example, the first plate 700 may be secured to the process chamber 100 below the support plate 210 and may enclose the tube 220.

The second plate 800 may be arranged between the support plate 210 and the first plate 700 and may be connected to a lower portion of the lift pin 600. When the susceptor 200 may move downward, the second plate 800 may be supported by the first plate 700 and thus the lift pin 600 may move upwards relatively to the support plate 210.

When the susceptor 200 may move upward, the lift pin 600 may move downward relatively to the support plate 210 and an upper portion of the lift pin 600 may penetrate through the penetration hole 212 and may be supported by an inner sidewall of the penetration hole 212. Thereafter, the lift pin 600 and the second plate 800 may move upward together with the susceptor 200.

Hereinafter, the wafer W may be loaded onto or unloaded from the susceptor 200 by the lift pin 600 and the second plate 800 as follows.

The susceptor 200 may move downward and the lift pin 600 may move upward relatively to the support plate 210. Then, the substrate W may be transferred into the process chamber 100 and be loaded onto the lift pin 600 by the transfer robot.

The susceptor 200 may move upward and thus the lift pin 600 and the wafer W may move downward relatively to the support plate 210. Thus, the wafer W may be positioned on the support plate 210 when the susceptor 200 may move upward. When the wafer W may be completely positioned on the support plate 210, the lift pin 600 and the second plate 800 may move to a predetermined position together with each other according as the susceptor 200 may move upward, to thereby locate the wafer W at a process position in the process chamber 100.

After completing the deposition process on the wafer W, the susceptor 200 may move downward and the second plate 800 may be positioned on the first plate 700. Then, the lift pin 600 may move upward relatively to the support plate 210 due to the downward movement of the susceptor 200. Therefore, the wafer W may be separated from the support plate 210.

When the wafer W may be separated from the support plate 210, the wafer W may be unloaded from the support plate 210 and transferred out of the process chamber 100 by the transfer robot.

In modified example embodiment, the lift pin 600 may be moved upward and downward by an additional driving unit (not shown). In such a case, the second plate 800 may be connected to the driving unit and both of the lift pin 600 and the second plate 800 may be moved by the driving unit and thus the wafer W may be loaded into or unloaded from the process chamber in accordance with the operation of the driving unit.

In another modified example embodiment, additional lift pins 600, for example three or more lift pins 600, may be prepared to improve support stability of the wafer W. In such a case, the support plate 210 may include additional penetration holes 212 corresponding to the additional lift pins 600, respectively.

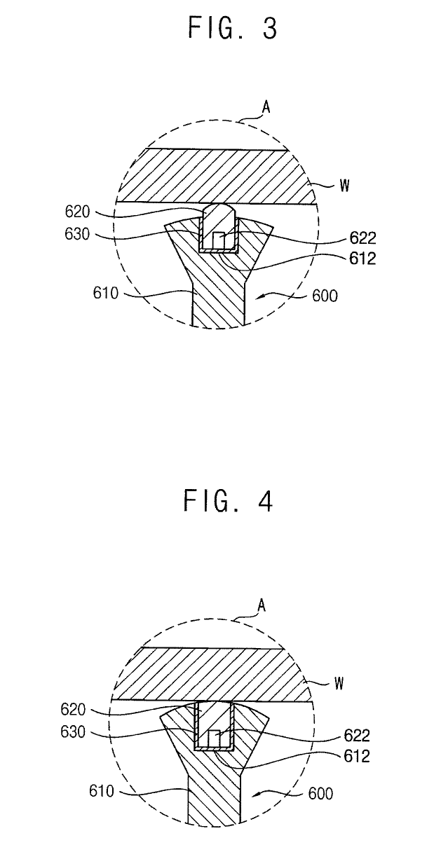

Hereinafter, detailed configurations of the lift pin 600 may be disclosed with reference to FIGS. 3 to 8. FIGS. 3 and 8 are enlarged views illustrating the lift pin shown in FIG. 2.

Referring to FIGS. 3 and 4, the lift pin 600 may include a body 610 and a contact member 620. The body 610 may be shaped into a rod extending in a vertical direction and have a shape and a size corresponding to the penetration hole 212 of the support plate 210 and thus may be movably inserted into the penetration hole 212. The body 610 may comprise a relatively hard material having hardness larger than that of silicon Si of the wafer W, to thereby have sufficient endurance while moving along the penetration hole 212.

For example, the body 610 may comprise one of anodized aluminum (Al), alumina (Al2O3), titanium (Ti), titanium nitride (TiN) and combinations thereof. Particularly, alumina (Al2O3) may have hardness of about 11.8 Gpa to about 16.0 Gpa significantly larger than the hardness of silicon (Si) in a range of about 10 Gpa to 10.5 Gpa.

A first recess 612 may be prepared at an upper portion of the body 610 and the contact member 620 may be positioned in the first recess 612 of the body 610. The contact member 620 may make contact with and support the wafer W.

For example, the contact member 620 may be positioned in the first recess 612 and be protruded from an upper surface of the body 610 in such a configuration that a top surface and a sidewall of the contact member 620 may be exposed to the space S of the process chamber 100 and the wafer W may make contact with the contact member 620, as shown in FIG. 3.

In contrast, the contact member 620 may be positioned in the first recess 612 in such a configuration that merely a top surface of the contact member 620 may be exposed to the space S of the process chamber 100 and thus the sidewall of the contact member 620 may make contact with an inner surface of the first recess 612 and the wafer W may make contact merely with the contact member 620, as shown in FIG. 4. In such a case, contaminants may be prevented from stacking on a boundary surface between the contact member 620 and the body 610.

The contact member 620 may comprise a relatively soft material having hardness smaller than that of silicon Si of the wafer W. For example, the contact member 620 may comprise a ceramic based material. Particularly, the contact member 620 may comprise yttrium oxide (Y2O3) having hardness of about 6.0 Gpa to about 6.5 Gpa significantly smaller than the hardness of silicon (Si) in a range of about 10 Gpa to 10.5 Gpa.

Therefore, the wafer W may be sufficiently prevented from being scratched by the lift pin 600 when the wafer W and the support plate 210 may be separated from each other by upward movement of the lift pin 600 since the hardness of the contact member 620 of the lift pin 600 is sufficiently smaller than that of the wafer W.

Further, a top surface of the contact member 620 may be shaped into a convex surface and thus the wafer W may make point contact with the contact member 620 of the lift pin 600, to thereby much more prevent the scratch on the wafer W.

In the present example embodiment, yttrium oxide (Y2O3) has much lower reactivity with respect to the plasma than any other ceramics and thus yttrium oxide (Y2O3) may be chemically reacted with the plasma of the reaction gases G much less than other ceramics. Thus, when the contact member 620 may comprise yttrium oxide (Y2O3), byproducts of the chemical reaction may be significantly reduced in depositing the reaction gases onto the wafer W, to thereby sufficiently reduce contamination of the wafer W caused by the byproducts of the deposition process.

Particularly, while alumina (Al2O3) may be reacted with fluorine (F) of the reaction gases G to thereby produce the byproducts of aluminum fluoride (AlF) on a surface of the wafer W, yttrium oxide (Y2O3) may be rarely reacted with the fluorine (F) at the same process conditions and thus no fluoride byproducts may be produced on the surface of the wafer W.

The aluminum fluoride (AlF) on the wafer W, which may be known as a mark failure, may cause aligning defect of optical members in a subsequent photolithography process. For those reasons, the body 610 of the lift pin 600, which may be positioned in the penetration hole 212, may comprise alumina (Al2O3) and the contact member 620, which may be exposed to the space S of the process chamber 100, may comprise yttrium oxide (Y2O3).

In an example embodiment, an adhering member 630 may be interposed between the inner surface of the first recess 612 and the sidewall of the contact member 620 to thereby secure the contact member 620 to the first recess 612 of the body 610. Examples of the adhering member 630 may comprise alumina (Al2O3), yttrium oxide (Y2O3), aluminum nitride (AlN) and silicon oxide (SiO2). These may be used alone or in combinations thereof.

An adhering material such as an adhesion paste may be coated on the inner surface of the first recess 612. The contact member 620 may be inserted into the first recess 612 having the adhesion paste and the adhesion paste may be hardened between the contact member 612 and the inner surface of the first recess 612. Therefore, the contact member 620 may be adhered to the adhering member 630 in the first recess and thus the contact member 620 may be secured to the inner surface of the first recess 612.

A residual air remaining in the first recess 612 may prevent the contact member 620 from inserting into the first recess 612 of the body 610. For preventing the air resistance in the first recess 612, an air reservoir 622 may be provided with the contact member 620. In the present example embodiment, a central portion of a bottom surface of the contact member 620 may be recessed to a predetermined depth to thereby form a central recessed portion at the bottom of the contact member 620 as the air reservoir 622.

Thus, when the contact member 620 may be inserted into the first recess 612 of the body 610, the residual air in the first recess 612 may be hold in the air reservoir 622, and thus the contact member 620 may be closely and tightly inserted into the first recess 612. Further, the air in the air reservoir 622 may function as an air cushion for the contact member 620 when the contact member 620 may be inserted into the first recess 612, to thereby prevent an instant impact of the contact member 620 against the bottom of the first recess 612.

Therefore, the contact member 620 may be closely and tightly inserted into the first recess 612 without any impact against the bottom by the adhering member 630 and the residual air that is to be exhausted through the air hole.

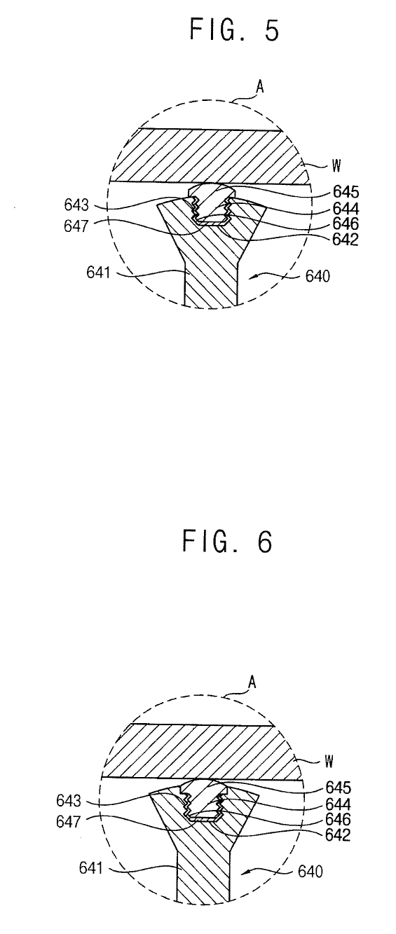

FIGS. 5 and 6 are cross sectional views illustrating a first modified example embodiment of the lift pin shown in FIG. 2.

Referring to FIGS. 5 and 6, the first modified lift pin 640 may include a body 641 and a contact member 644. The body 641 may have a shape and a size corresponding to the penetration hole 212 of the support plate 210 and thus may be movably inserted into the penetration hole 212.

The body 641 may include a first recess 642 at an upper portion thereof and the contact member 644 may be screwed into the first recess 642 in such a configuration that an upper portion 645 of the contact member 644, which may correspond to a head portion of a screw, may be protruded from the upper portion of the body 641.

Particularly, first screw threads 646 may be prepared on a sidewall of the contact member 644 and second screw threads 643 engaged with the first screw threads may be prepared on an inner surface of the first recess 642 of the body 641.

An adhering member 647 may be further coated on the inner surface of the first recess 642 to thereby firmly secure the contact member 644 to the first recess 642.

For example, the contact member 644 may be positioned in the first recess 642 and be protruded from an upper surface of the body 641 in such a configuration that the upper portion 645 and the sidewall of the contact member 644 may be exposed to the space S of the process chamber 100 and the wafer W may make contact with the contact member 644, as shown in FIG. 5.

In contrast, the contact member 644 may be positioned in the first recess 642 in such a configuration that merely the upper portion 645 of the contact member 644 may be exposed to the space S of the process chamber 100 and thus most of the sidewall of the contact member 644 may be screwed up with the inner sidewall of the first recess 642, as shown in FIG. 6.

In addition, the upper portion 645 may be further removed from the contact member 644 and residual of the contact member 644 except for the upper portion 645 may be accurately fit into the first recess 642. In such a case, contaminants may be prevented from stacking on the boundary surface between the body 641 and the contact member 644 since the first and second screw threads may be closely and tightly engaged with each other at the boundary area.

For example, a diameter of the upper portion 645 of the contact member 644 may be larger than that of the first recess 642 and thus the upper portion 645 of the contact member 644 may function as a stopper when the contact member 644 may be screwed up into the first recess 642. Further, the upper portion 645 of the contact member 644 may be shaped into a convex curve and thus the wafer W may make point contact with the contact member 644.

Accordingly, the contact member 644 may be screwed up into the first recess 642 of the body 641 by a screw joint and thus the body 641 and the contact member 644 may be sufficiently secured to each other in the first modified lift pin 640. Therefore, there is little possibility that the contact member 644 and the body 641 may be separated from each other and thus the first modified lift pin 640 may be broken in the deposition process.

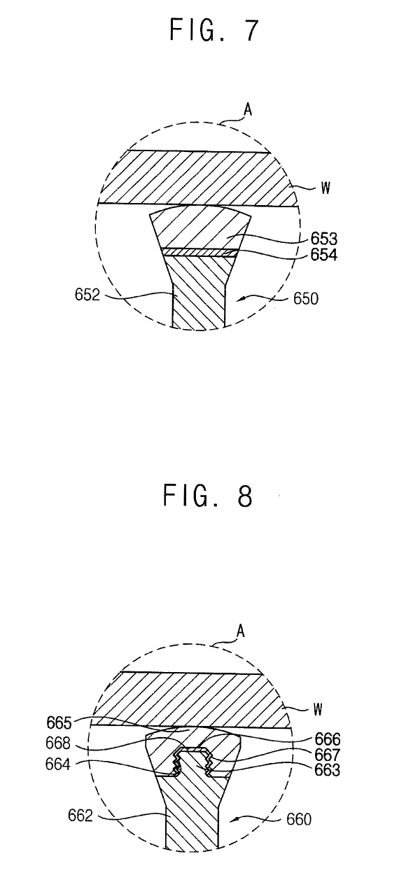

FIG. 7 is a cross sectional view illustrating a second modified example of the lift pin shown in FIG. 2.

Referring to FIG. 7, the second modified lift pin 650 may include a body 652 and a contact member 653. The body 652 may have a shape and a size corresponding to the penetration hole 212 of the support plate 210 and thus may be movably inserted into the penetration hole 212.

The body 652 may include a flat upper surface and the contact member 653 may be coupled onto the flat surface of the body 652 by a thermal compression process at a high temperature. In the present example embodiment, the body 652 may comprise alumina (Al2O3) and the contact member 653 may comprise yttrium oxide (Y2O3).

When the thermal compression process may be performed on the alumina body 652 and the yttrium contact member 653, a contact portion of the body 652 and the contact member 653 may be partially melted and a phase transition layer 654 may be generated on the upper surface of the body 652. That is, the phase transition layer 654 may be interposed between the body 652 and the contact member 653 due to the thermal compression process.

When the thermal compression process may be performed at a temperature below about 900° C., the contact portion of the body 652 and the contact member 653 may be difficult to be melted, while at a temperature above about 1,100° C., most of the body 652 and the contact member 653 may be likely to be melted away. Thus, the thermal compression may be performed at a temperature of about 900° C. to about 1,100° C.

As a result, the phase transition layer 654 may comprise yttrium aluminum garnet (YAG) due to a chemical reaction of yttrium oxide (Y2O3) and alumina (Al2O3).

Therefore, the contact member 653 may be secured to the body 652 due to a combining force of the phase transition layer 654. Particularly, the thermal compression process may be performed on a plurality of contact members 653 and a plurality of bodies 652, and thus a plurality of the pair of the contact members 653 and the bodies 652 may be simultaneously secured to each other, respectively. In addition, an upper portion of the contact member 653 may be shaped into a convex curve and thus the wafer W may make point contact with the contact member 653.

FIG. 8 is a cross sectional view illustrating a third modified example of the lift pin shown in FIG. 2.

Referring to FIG. 8, the third modified lift pin 660 may include a body 662 and a contact member 665. The body 662 may have a shape and a size corresponding to the penetration hole 212 of the support plate 210 and thus may be movably inserted into the penetration hole 212.

The body 662 may include a protrusion 663 at an upper portion thereof and the contact member 665 may include a second recess 666 into which the protrusion 663 may be inserted by a screw joint.

In an example embodiment, third screw threads 664 may be prepared on a side surface of the protrusion 663 and fourth screw threads 667, which may be engaged with the third screw threads, may be prepared on an inner sidewall of the second recess 666. Thus, the protrusion 663 of the body 662 may be sufficiently secured to the second recess of the contact member 665 by a screw joint of the third and fourth screw threads.

In addition, an adhering member 668 may be further coated on the inner surface of the second recess 666 of the contact member 665, to thereby by reinforce the joint of the body 662 and the contact member 665. For example, the adhering member 668 may comprise ceramic materials.

### INDUSTRIAL APPLICABILITY

According to the example embodiments of the present inventive concept, the lift pin may be separated into body and contact member making contact with the wafer and merely the contact member may comprise a soft material having hardness smaller than that of silicon (Si) of the wafer, to thereby prevent the scratch defect from the surface of the wafer in performing the deposition process on the wafer.

Further, merely the contact member may comprise yttrium oxide (Y2O3), which may be extremely expensive than any other materials. Particularly, the contact member of the lift pin may be shaped into a minimal size just enough to support the wafer and the body of the lift pin may comprise an inexpensive material having good hardness, to thereby reduce manufacturing cost of the lift pin.

In addition, the contact member and the body of the lift pin may be secured to each other by a screw joint and an adhering member, to thereby reduce the fracture of the lift pin caused by the separation of the contact member and the body.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A lift pin for moving a substrate upward or downward on a susceptor in an apparatus for processing the substrate positioned on the susceptor, comprising:
a body inserted into a penetration hole of the susceptor and moving along the penetration hole upward and downward in a direction vertical to an upper surface of the susceptor; and
a contact member secured to an upper portion of the body and comprising a soft material having hardness smaller than that of the substrate.

2. The lift pin of claim 1, wherein the contact member comprises yttrium oxide (Y2O3).

3. The lift pin of claim 1, wherein the body includes a recess portion at the upper portion thereof and the contact member is inserted into the recess portion in such a configuration that an upper portion of the contact member is protruded from the upper portion of the body.

4. The lift pin of claim 3, further comprising an adhering member positioned on an inner surface of the recess portion of the body, so that the contact member is adhered to the inner surface of the recess portion of the body.

5. The lift pin of claim 3, wherein the contact member includes an air reservoir at a central bottom portion thereof, so that a residual air remaining in the recess portion of the body is hold in the air reservoir when the contact member is inserted into the recess portion of the body.

6. The lift pin of claim 3, wherein first screw threads are prepared on a sidewall of the contact member and second threads are prepared on an inner surface of the recess portion of the body, so that the contact member is secured into the recess portion of the body by a screw joint.

7. The lift pin of claim 1, further comprising a phase transition layer interposed between the contact member and the body, so that the contact member is secured to the body by a combining force of the phase transition layer.

8. The lift pin of claim 7, wherein the phase transition layer comprises yttrium aluminum garnet (YAG) on condition that the contact member comprises yttrium oxide (Y2O3) and the body comprising alumina (Al2O3).

9. The lift pin of claim 1, wherein the body includes a protrusion at the upper portion thereof and the contact member includes a recess into which the protrusion is inserted.

10. The lift pin of claim 9, wherein third screw threads are prepared on a sidewall of the protrusion and fourth screw threads are prepared on an inner surface of the recess, so that the protrusion of the body is inserted into the recess of the contact member by a screw joint.

11. The lift pin of claim 10, further comprising an adhering member positioned on an inner surface of the recess of the contact member.

12. An apparatus for processing a substrate, comprising:
a process chamber into which reaction gases for processing the substrate are supplied and providing a space for performing the process;
a susceptor arranged in the process chamber and having a penetration hole, the substrate being positioned on the susceptor;
an electrode arranged over the susceptor and to which an electronic power is applied, the reaction gases being transformed into plasma in the space of the process chamber by the electronic power; and
a lift pin movably inserted into the penetration hole of the susceptor and lifting the substrate from the susceptor, the lift pin including a body inserted into the penetration hole and moving along the penetration hole upward and downward in a direction vertical to an upper surface of the susceptor and a contact member secured to an upper portion of the body and comprising a soft material of which a hardness is smaller than that of the substrate.
